(19) United States
(12) Patent Application Publication
(10) Pub. No.: US 2015/0069634 A1
(43) Pub. Date: Mar. 12, 2015

(54) SEMICONDUCTOR DEVICE

(71) Applicant: KABUSHIKI KAISHA TOSHIBA, Tokyo (JP)

(72) Inventors: Yukifumi OYAMA, Mie (JP); Hideko MUKAIDA, Tokyo (JP); Masatoshi FUKUDA, Mie (JP); Satoshi TSUKIYAMA, Kanagawa (JP); Shinya FUKAYAMA, Aichi (JP)

(73) Assignee: KABUSHIKI KAISHA TOSHIBA, Tokyo (JP)

(21) Appl. No.: 14/194,783

(22) Filed: Mar. 2, 2014

(30) Foreign Application Priority Data
Sep. 9, 2013 (JP) 2013-185861

(51) Int. Cl. H01L 23/00

(52) U.S. Cl. CPC H01L 23/562
USPC 257/777

(57) ABSTRACT

According to one embodiment, a semiconductor device includes a first semiconductor chip having a first main surface and a second main surface which opposes the first main surface and on which a first electrode is mounted, a second semiconductor chip having a third main surface on which a second electrode connected to the first electrode is provided and a fourth main surface which opposes the third main surface, and a first spacer which is arranged in a region formed between the first and second electrodes and an outer peripheral surface of the first and second semiconductor chips, and ensures a gap between the first semiconductor chip and the second semiconductor chip.

### CROSS-REFERENCE TO RELATED APPLICATION

This application is based upon and claims the benefit of priority from Japanese Patent Application No. 2013-185861, filed Sep. 9, 2013, the entire contents of which are incorporated herein by reference.

### FIELD

An embodiment described herein relates generally to a semiconductor device in which a semiconductor chip is mounted to a support or lead frame to provide a packaged device.

### BACKGROUND

A known semiconductor device includes a plurality of laminated (stacked) semiconductor chips in a sealed package. In such a semiconductor device, the semiconductor chips are laminated one over the other in a stepwise displaced manner such that electrodes located along an edge or edges of the respective semiconductor chips remain exposed when the next semiconductor chip is located thereover, such that the electrodes of the respective semiconductor chips may electrically connected to each other by bonding wires connected to the semiconductor chip electrodes. However, recently, a semiconductor device has been developed and put into practice where connection bumps are mounted on the front surface and the back surface of the semiconductor chips, to electrically connect the semiconductor chips to each other.

In such a semiconductor device where the plurality of semiconductor chips are laminated, i.e., stacked and interconnected one over the other, to achieve the miniaturization of the semiconductor device or to reduce a thickness of the semiconductor device, a thickness of the semiconductor chip is typically extremely small and hence, the semiconductor chip is subject to be deformation or warping due to internal stresses therein. Accordingly, when the semiconductor chip is laminated, the semiconductor chip is deformed so that strain is present in the region of the connection bump. When strain is generated in the region of the connection bump, the chip and/or the connection bump may be deformed making it possible that the semiconductor chips are not electrically or mechanically connected to each other.

### DESCRIPTION OF THE DRAWINGS

FIG. 1A and FIG. 1B are schematic cross-sectional views of a semiconductor device according to an embodiment.

FIG. 2 is arrangement plan view of spacers according to the embodiment.

FIG. 3 is an arrangement view of spacers according to a comparison example.

FIG. 4A to FIG. 4F are views showing arrangement positions of spacers and bump electrodes of an example.

FIG. 5 is a graph showing strain in a bump and a deformation amount of a semiconductor chip.

FIG. 6A to FIG. 6C are views showing one example of a spacer arrangement of the example.

### DETAILED DESCRIPTION

According to an embodiment, there is provided a semiconductor device where the generation of strain in connection bumps due to the deformation of a semiconductor chip can be minimized.

In general, according to one embodiment, a semiconductor device includes: a first semiconductor chip having a first main surface and a second main surface which opposes the first main surface and on which a first electrode is mounted; a second semiconductor chip having a third main surface on which a second electrode connected to the first electrode is provided and a fourth main surface which opposes the third main surface; and a first spacer which is arranged in a region formed between the first and second electrodes and outer peripheral surfaces of the first and second semiconductor chips, and ensures a gap between the first semiconductor chip and the second semiconductor chip.

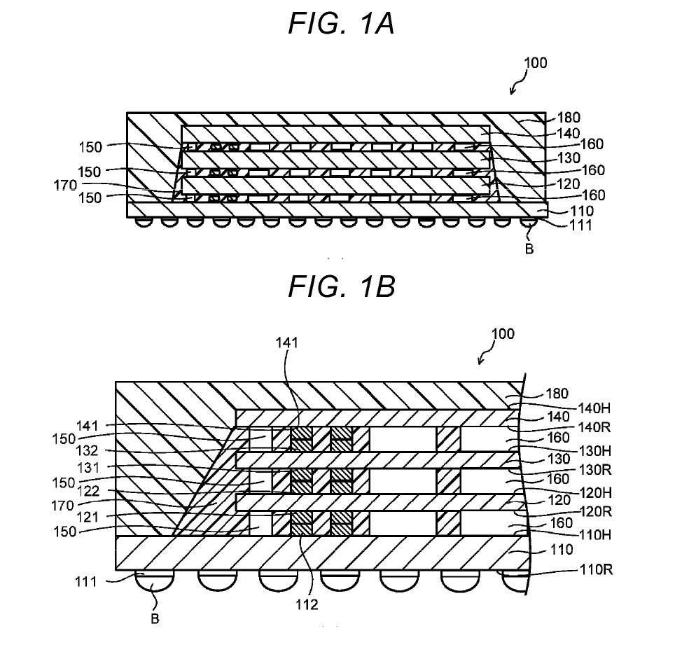

Hereinafter, one embodiment of a method of manufacturing a semiconductor device, and a semiconductor manufacturing device is explained in conjunction with FIGS. 1, 2 and 4A-6C. In the respective embodiments, substantially the same constitutional parts are given the same reference numerals, and repeated explanation of the same parts is omitted for brevity. However, the semiconductor device is schematically shown in the drawings and hence, the relationship between thicknesses and planar sizes, ratio between thicknesses of respective layers, scale, and the like, differ from those of a semiconductor device which is actually manufactured. Terms which indicate directions such as “up” and “down” in the explanation made hereinafter indicate the relative directions and may not indicate the directions according to gravitational force.

### Embodiment

FIG. 1A and FIG. 1B are sectional views of a semiconductor device 100 according to the embodiment. FIG. 1A is a cross-sectional view of the semiconductor device 100, and FIG. 1B is a cross-sectional view showing an enlarged portion of the semiconductor device 100 shown in FIG. 1A. The semiconductor device 100 is a semiconductor device having the MCP (multi chip package) structure where a plurality of semiconductor chips are laminated to each other and sealed in one package.

The semiconductor device 100 includes: a circuit board 110; semiconductor chips 120, 130 and 140; first spacers 150; second spacers 160; an underfill resin 170; and a sealing resin 180. Although the semiconductor device 100 of this embodiment has the structure where three semiconductor chips 120 to 140 are laminated to each other, the number of laminated semiconductor chips is not limited provided that the number of laminated semiconductor chips is at least two, or more.

The circuit board 110 is a board on which the semiconductor chips 120, 130 and 140 are mounted. A plurality of outer connection terminals 111 are mounted on aback surface (first main surface) 110R of the circuit board 110, and a plurality of bump electrodes 112 which are connected to the semiconductor chip 120 are mounted on a front surface (second main surface) 110H of the circuit board 110 respectively. Each outer connection terminal 111 is coated with a solder thus forming a solder ball B.

The semiconductor chips 120, 130 and 140 are formed as a memory chip or a controller chip, for example, respectively. A plurality of bump electrodes 121 which are connected to the bump electrodes 112 on the circuit board 110 are mounted on a back surface (first main surface) 120R of the semiconductor chip 120, and a plurality of bump electrodes 122 which are connected to the semiconductor chip 130 are mounted on a front surface (second main surface) 120H of the semiconductor chip 120.

Bump electrodes 131, which are connected to the bump electrodes 122 on the semiconductor chip 120, are mounted on a back surface (first main surface) 130R of the semiconductor chip 130, and bump electrodes 132 which are connected to the semiconductor chip 140 are mounted on a front surface (second main surface) 130H of the semiconductor chip 130.

Bump electrodes 141 which are connected to the bump electrodes 132 on the semiconductor chip 130 are mounted on a back surface (first main surface) 140R of the semiconductor chip 140. In FIG. 1A and FIG. 1B, three semiconductor chips are laminated to each other. Accordingly, although bump electrodes are not mounted on a front surface (second main surface) 140H of the semiconductor chip 140 on the uppermost stage, bump electrodes may be mounted on the front surface (second main surface) 140H of the semiconductor chip 140 if additional semiconductor chips (not shown) are to be laminated thereon.

The respective bump electrodes 121, 122, 131, 132, 141 mounted on the semiconductor chips 120, 130 and 140 may comprise a material combination, such as the combination of a solder and different solder. Examples include the combination of Au and a solder, the combination of a solder and Au, and the combination of Au and Au. As a solder for forming the respective bump electrodes 121, 122, 131, 132, 141, a Pb free solder which uses an Sn alloy formed by adding Cu, Ag, Bi, In, or the like, to Sn may be used. As a specific example of a Pb free solder, an Sn—Cu alloy, an Sn—Ag alloy, an Sn—Ag—Cu alloy and the like may be used.

Cu, Ni, Sn, Pd, Ag or the like may be used in place of Au as metal for forming the respective bump electrodes 121, 122, 131, 132, 141. The film structure of these bump electrodes is not limited to a single-layer film, and these bump electrodes may be formed of a laminated layer film comprising a plurality of films made of different metals. Although a projecting shape, such as a semispherical shape or a columnar shape is exemplified as the shapes of the respective bump electrodes 121, 122, 131, 132, 141 in FIGS. 1A and 1B, the respective bump electrodes 121, 122, 131, 132, 141 may have flat shape like a pad. A combination of projections, a combination of projections and flat bodies, and the like, may be used as shapes for the respective bump electrodes 121, 122, 131, 132, 141.

The first and second spacers 150, 160 are arranged between the circuit board 110 and the semiconductor chip 120, between the semiconductor chip 120 and the semiconductor chip 130, and between the semiconductor chip 130 and the semiconductor chip 140 to provide a gap between the circuit board 110 and the respective semiconductor chips 120 to 140 to equal a combined height, or slightly less, of the bump electrodes.

The first and second spacers 150, 160 are preferably made of a thermosetting resin such as an epoxy resin, a polyimide resin, an acrylic resin or a phenol resin, for example. The first and second spacers 150, 160 may be formed by using a lithography technique, a technique which applies a resin coating using a dispenser or by a technique where the spacers are formed by adhering films. In forming the first and second spacers 150, 160 by applying a thermosetting resin composition in a liquid form by coating, the first and second spacers 150, 160 are brought into a semi-cured state before adhesion to the semiconductor chip. Alternatively, in forming the first and second spacers 150, 160 by applying a thermosetting resin composition, the time necessary for adhesion of the semiconductor chip or a time for connection of the semiconductor chip may be minimized by using a fast-curing type material.

The underfill resin 170 is filled in the gap formed between the circuit board 110 and the gaps between the semiconductor chips 120 to 140. By arranging the first and second spacers 150, 160 in the gaps, it is possible to increase a connection strength between the circuit board 110 and the semiconductor chips 120, 130 and 140 before the underfill resin 170 is filled in the gaps from the side of the stack of semiconductor chips.

A sealing resin 180, formed of an epoxy resin, for example, is formed over the semiconductor chips 120, 130 and 140 mounted on the circuit board 110 to seal or encapsulate the on the circuit board 110.

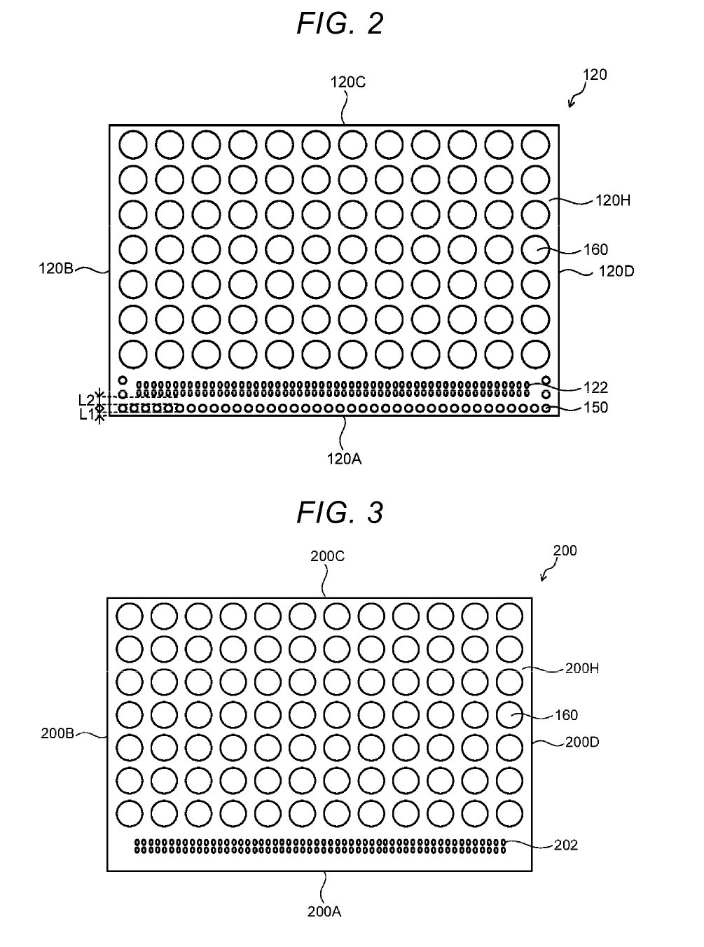

FIG. 2 is a view showing the arrangement positions of the first and second spacers 150, 160 of this embodiment. To be more specific, FIG. 2 shows the arrangement positions of the first and second spacers 150, 160 mounted on the front surface (second main surface) 120H of the semiconductor chip 120.

As shown in FIG. 2, the semiconductor chip 120 has a rectangular shape as viewed in a top plan view, and has four outer peripheral surfaces 120A to 120D. The plurality of bump electrodes 122 are mounted in two rows along the outer peripheral surface 120A of the semiconductor chip 120.

The first spacers 150 are arranged between the plurality of bump electrodes 122 and the outer peripheral surface 120A closest to the bump electrodes 122 and at a position where a distance L1 (shown in FIG. 2) between the first spacers 150 and the outer peripheral surface 120A of the semiconductor chip 120 is less than a distance L2 between the first spacers 150 and the plurality of bump electrodes 122. The distance L1 is the shortest distance from outer peripheral surfaces of the first spacers 150 to the outer peripheral surface 120A. The distance L2 is the shortest distance from the outer peripheral surfaces of the first spacers 150 to outer peripheral surfaces of the bump electrodes 122.

FIG. 2 is a plan view of the semiconductor device 100 of FIGS. 1A and 1B across the interface between semiconductor chips 120 and 130 (shown in FIGS. 1A and 1B), specifically between the bump electrodes 122 and 131 (shown in FIGS. 1A and 1B). As shown in FIG. 2, in this embodiment, the first spacers 150 for ensuring the gap between the semiconductor chip 120 and the semiconductor chip 130 are arranged between the plurality of bump electrodes 122 and the outer peripheral surface 120A closest to the bump electrodes 122. The first spacers 150 maintain a gap between the semiconductor chips 120 and 130 and prevent a bending moment during joining of the semiconductor chips 120 and 130. Accordingly, in joining the semiconductor chip 120 and the semiconductor chip 130 to each other by pressure bonding, it is possible to suppress a deformation generated in the vicinity of outer peripheries of the semiconductor chips 120, 130 since the first spacers 150 are disposed on the extreme outer periphery thereof. As a result, strain in the bump electrodes 122, 131 due to the deformation of the semiconductor chips 120, 130 may be minimized. Accordingly, damage (collapse) of the bump electrodes 122, 131 or the occurrence of a connection failure (open failure) between the bump electrodes 122, 131 may be suppressed.

The first spacers 150 are arranged at the position where the distance L1 between the first spacers 150 and the outer peripheral surface 120A of the semiconductor chip 120 is shorter than the distance L2 between the first spacers 150 and the plurality of bump electrodes 122. Due to such an arrangement, the deformation of the semiconductor chips 120, 130 which is generated in the vicinity of the outer peripheries of the semiconductor chips 120, 130 may be effectively minimized, because the spacers prevent undue deformation of the semiconductor chips during the pressure bonding thereof the each other or the circuit board.

The arrangement positions of the first and second spacers 150, 160 shown in FIG. 2 are equally applicable to the arrangement positions of the first and second spacers 150, 160 mounted on other semiconductor chips 130, 140 and hence, the repeated explanation of the arrangement positions of the first and second spacers 150, 160 mounted on other semiconductor chips 130, 140 is omitted for brevity. The arrangement positions of the first and second spacers 150, 160 on other semiconductor chips 130, 140 can acquire substantially the same advantageous effect as the arrangement positions of the first and second spacers 150, 160 shown in FIG. 2.

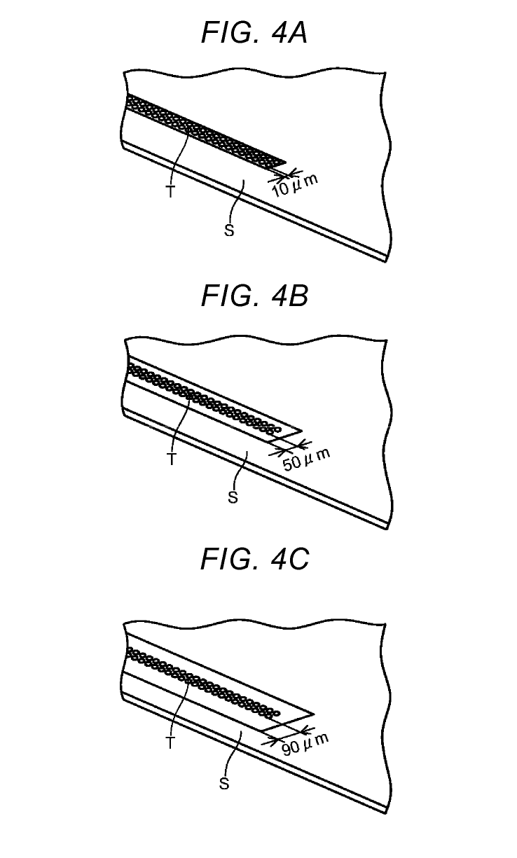

FIG. 3 is a view showing the arrangement positions of first and second spacers 150, 160 of a comparison example. FIG. 3 shows the arrangement positions of the first and second spacers 150, 160 mounted on a front surface (second main surface) 200H of a semiconductor chip 200. The features identical with the constitutions explained in conjunction with FIG. 1A, FIG. 1B and FIG. 2 are given the same symbols, and the repeated explanation of the features is omitted.

As shown in FIG. 3, the semiconductor chip 200 has a rectangular shape as viewed in a top plan view, and has four outer peripheral surfaces 200A to 200D. A plurality of bump electrodes 202 are mounted in two rows along the outer peripheral surface 200A of the semiconductor chip 200.

As shown in FIG. 3, spacers are not arranged between the plurality of bump electrodes 202 and the outer peripheral surface 200A closest to the bump electrodes 202. Accordingly, in joining another semiconductor chip (not shown in the drawing) to the semiconductor chip 200 by pressure bonding, a strain is generated in the vicinity of outer peripheries of the semiconductor chip 200. Without the spacers, the strain generated on the semiconductor chip 200 from the pressure bonding cannot be suppressed and the semiconductor chip 200 may deform. As a result, a strain is generated in the bump electrodes 202 due to the deformation of the semiconductor chip. Without the spacers, the strain in the bump electrodes cannot be suppressed thus giving rise to a possibility that the bump electrodes 202 may be damaged (collapse of the bump electrodes 202) or a connection failure (open failure) may occur between the bump electrodes 202 and bump electrodes on another semiconductor chip.

### Examples

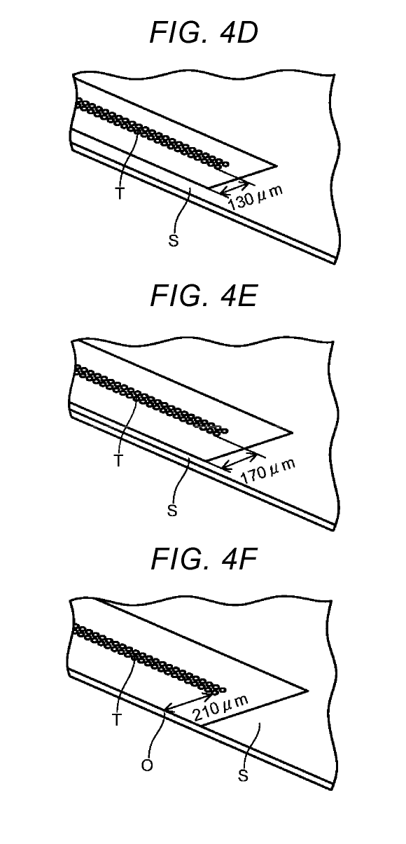

FIG. 4A to FIG. 4F are views showing the exemplary arrangement positions (locations) of spacers S (corresponding to the first and second spacers 150, 160 in FIG. 1A and FIG. 1B) and bump electrodes T (corresponding to the bump electrodes 121, 122, 131, 132, 141 in FIG. 1A and FIG. 1B) on a semiconductor chip. FIG. 4A to FIG. 4F show examples where a distance between the spacers 150 and the bump electrodes 122 is set to 10 μm, 50 μm, 90 μm, 130 μm, 170μm and 210 μm, respectively. In FIG. 4F, the spacers 150 are not provided between the bump electrodes 122 and an outer peripheral surface O of a semiconductor chip

Next, with respect to the examples shown in FIG. 4A to FIG. 4F, strain generated in the bump electrodes 122 and a deformation amount of the semiconductor chip which are generated when the semiconductor chip is laminated are obtained by simulation.

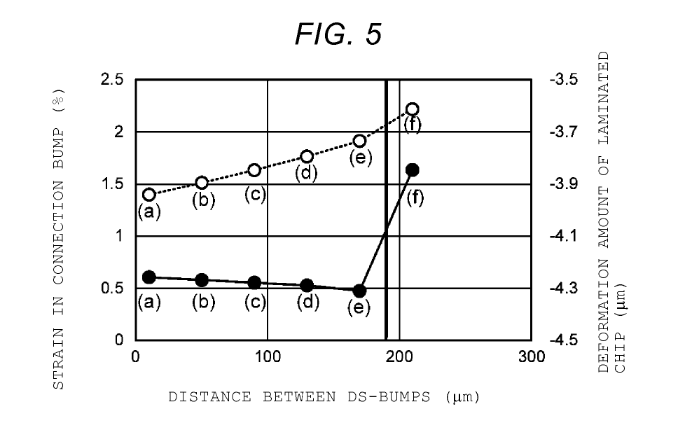

FIG. 5 shows the result of simulation with respect to the respective examples shown in FIG. 4A to FIG. 4F. Data points (a)-(f) in the graph correspond to the exemplary positions of the spacers 150 shown in FIG. 4A to FIG. 4F, respectively. In FIG. 5, a strain (%) generated in the bump electrodes 122 is shown on a left ordinate axis, and a deformation amount (μm) of the semiconductor chip is shown on a right ordinate axis. The strain generated in the bump electrode 122 is expressed as a displacement of a material point in the bump electrode 122 with respect to a reference length (in an initial state) of the bump electrode 122. That is, a strain generated in the bump electrode 122 is a scale indicating the deformation of the bump electrode 122. The upward deformation amount of the semiconductor chip is set as the positive deformation amount.

As shown in FIG. 5, it is found that the greater the distance between the spacer 150 and the bump electrode 122 becomes, the greater a strain (%) in the bump electrode 122 and a deformation amount (μm) of the semiconductor chip become. Further, as shown in FIG. 4F, it is found that when the spacer S is not provided between the bump electrode 122 and the outer peripheral surface O of the semiconductor chip, a deformation amount (μm) of the semiconductor chip is sharply increased.

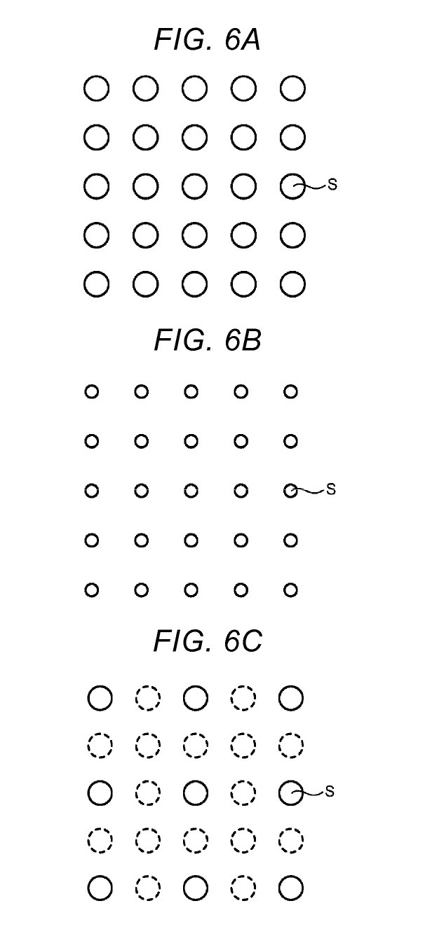

FIG. 6A to FIG. 6C are views showing the arrangement of the spacers 150 according to some examples. In these examples, a rate of change in warping of a semiconductor chip is obtained with respect to the respective arrangements of spacers 150 (corresponding to first and second spacers 150, 160 in FIG. 1A and FIG. 1B) shown in FIG. 6A to FIG. 6C. Table 1 shows “diameter of spacer”, “pitch (interval from space center to the center of the next spacer”, “spacer occupying area ratio (percent of the semiconductor chip area covered by the spacers” and “amount of change in warping” with respect to the examples shown in FIG. 6A to FIG. 6C.

TABLE 1

| Arrangement | FIG. 6A | FIG. 6B | FIG. 6C |
|---|---|---|---|
| diameter of spacer (μm) | 40 | 20 | 40 |
| pitch (μm) | 80 | 80 | 160 |
| spacer occupying area ratio (%) | 19.6 | 4.9 | 4.9 |
| amount of change in warping (%) | reference | 22 | 4 |

“amount of change in warping” in Table 1 shows the degree of change in an amount of warping in the examples shown in FIG. 6B and FIG. 6C with reference to an amount of warping in the semiconductor chip shown in FIG. 6A. “Pitch (arrangement interval)” means a distance between the centers of the spacers 150.

From the result shown in Table 1, it is found that if a ratio of the area occupied by the spacers 150 is equal, the larger the diameter of the spacer 150 is, the more effectively warping of the semiconductor chip may be minimized. Accordingly, the diameter of the spacer 150 may be as large as possible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor chip having a first main surface and a second main surface which opposes the first main surface and on which a first electrode is formed;
a second semiconductor chip having a third main surface on which a second electrode is formed that is connected to the first electrode and a fourth main surface which opposes the third main surface; and
a first spacer provided in a region of the first and second semiconductor chips outward of the first and second electrodes, and the first spacer providing a gap between the first semiconductor chip and the second semiconductor chip.

2. The semiconductor device according to claim 1, wherein
the first and the second electrodes are provided along the outer peripheral surfaces of the first and second semiconductor chips, and
the first spacer is provided between the first and second electrodes and an outer peripheral surface of the first and second semiconductor chips.

3. The semiconductor device according to claim 2, wherein
the first spacer is provided at a position where a distance between the first spacer and the outer peripheral surfaces of the first and second semiconductor chips is less than a distance between the first spacer and the first and second electrodes.

4. The semiconductor device according to claim 2, wherein
a second spacer is provided in a region inward of the first and second electrodes.

5. The semiconductor device according to claim 1, wherein
the first spacer is provided at a position where a distance between the first spacer and the outer peripheral surfaces of the first and second semiconductor chips is less than a distance between the first spacer and the first and second electrodes.

6. The semiconductor device according to claim 5, wherein
a second spacer provided in a region other than the region outward of the first and second electrodes and the outer peripheral surfaces of the first and second semiconductor chips.

7. The semiconductor device according to claim 1, further comprising:
a second spacer provided in a region other than the region outward of the first and second electrodes and the outer peripheral surfaces of the first and second semiconductor chips.

8. A semiconductor device comprising:
a circuit board having a back surface opposing a front surface; and
a plurality of semiconductor chips sequentially stacked on the front surface of the circuit board and being electrically connected by a respective electrode disposed adjacent an outer edge of each of the semiconductor chips, wherein
a first spacer is disposed between the electrodes and the outer edge of each of the semiconductor chips.

9. The semiconductor device of claim 8, wherein the first spacer maintains a gap between each of the plurality of semiconductor chips.

10. The semiconductor device according to claim 9, further comprising:
a second spacer disposed in a region of the semiconductor chip interior from the position of the electrodes.

11. The semiconductor device of claim 10, wherein the first spacer and the second spacer comprise the same height.

12. The semiconductor device according to claim 8, wherein
the first spacer is provided at a position where a distance between the first spacer and the outer edge of the semiconductor chips is less than a distance between the first spacer and the electrodes.

13. The semiconductor device according to claim 12, further comprising:
a second spacer disposed in a region interior of the semiconductor chip from the position of the electrodes.

14. A semiconductor device comprising:
a circuit board having a back surface opposing a front surface; and
a plurality of semiconductor chips sequentially stacked on the front surface of the circuit board, at least one of the plurality of semiconductor chips being electrically connected to the circuit board and by a first electrode, wherein
each of the plurality of semiconductor chips comprises:
a plurality of second electrodes disposed linearly adjacent a peripheral edge of each of the semiconductor chips, and
a plurality of first spacers positioned between the second electrode and the peripheral edge.

15. The semiconductor device of claim 14, wherein the plurality of first spacers maintain a gap between each of the plurality of semiconductor chips.

16. The semiconductor device according to claim 15, further comprising:
a plurality of second spacers disposed in a region interior of the second electrodes.

17. The semiconductor device of claim 16, wherein the each of the plurality of first spacers and the plurality of second spacers comprise the same height.

18. The semiconductor device according to claim 14, wherein
the plurality of first spacers are provided at a position where a distance between the one of the plurality of first spacers and the outer edge of the semiconductor chips is less than a distance between one of the plurality of first spacers and the electrodes.

19. The semiconductor device according to claim 18, further comprising:
a plurality of second spacers disposed in a region of the semiconductor chip which is interior of the second electrodes.

20. The semiconductor device according to claim 14, further comprising:
a plurality of second spacers disposed in a region interior of the second electrodes.
